(19) United States
(12) Patent Application Publication
(10) Pub. No.: US 2018/0019159 A1
(43) Pub. Date: Jan. 18, 2018

(54) SEMICONDUCTOR DEVICE AND MANUFACTURING METHOD THEREFOR, AND ELECTRONIC DEVICE

(71) Applicant: CSMC TECHNOLOGIES FAB2 CO., LTD., Jiangsu (CN)

(72) Inventors: Wei LI, Jiangsu (CN); Long HAO, Jiangsu (CN); Yan JIN, Jiangsu (CN)

(21) Appl. No.: 15/548,257

(22) PCT Filed: Jan. 29, 2016
(86) PCT No.: PCT/CN2016/072743

§ 371 Date: Aug. 2, 2017

(30) Foreign Application Priority Data
Feb. 2, 2015 (CN) 201510054233.4

(51) Int. Cl. H01L 21/762; H01L 21/265; H01L 21/02

(52) U.S. Cl. CPC H01L 21/76224; H01L 21/0217; H01L 21/26513

(57) ABSTRACT

A manufacturing method for a semiconductor device, comprising: providing a semiconductor substrate (100), and forming a shallow trench isolation structure (104) in the semiconductor substrate (100); forming a gate structure comprising a gate oxidation layer (105a) and a gate material layer (105b) that are stacked from the bottom up on the semiconductor substrate (100); executing first ion implantation so as to form first doping ions in the gate material layer (105b), and executing second ion implantation (109) so as to form second doping ions at the part of the gate material layer (105b) that is located over a top corner of the shallow trench isolation structure(104), the second doping ions and the first doping ions being opposite in conduction type.

### FIELD OF THE INVENTION

The present disclosure relates to a field of semiconductor manufacturing processes, and more particularly relates to a semiconductor device and a method of manufacturing the same and an electronic device using the same.

### BACKGROUND OF THE INVENTION

In a conventional process of manufacturing integrated circuits, there is a process of manufacturing a high voltage (HV) device, which usually uses a thicker (thickness greater than 200 angstroms) thermal oxide layer as a gate oxide layer of the HV device. Since the structure characteristics of a shallow trench isolation (STI) itself, the gate oxide layer grown on a top corner of the STI is usually much thinner than the gate oxide layer grown on a planer active region. However, it is generally difficult to improve the thickness of the gate oxide layer formed on the top corner of the STI by process adjustment. The difference in thickness of the aforementioned gate oxide layer and an edge effect on the top corner of the STI cooperatively cause the gate voltage to drain current (VG-ID) curve of the HV device to behave a double humps phenomenon, a curve of data 1 in FIG. 2 is shown. This double humps phenomenon indicates that the HV device has a higher static leakage current and a lower threshold voltage, therefore this phenomenon needs to be eliminated as much as possible.

In order to improve the double humps effect of the HV device manufactured by adopting the conventional manufacturing process, it is a common method to improve the thickness of the gate oxide layer formed on the top corner of the STI in semiconductor field, which specifically includes the steps of: providing a semiconductor substrate, and forming a pad oxide layer and a silicon nitride layer on the semiconductor substrate sequentially, and the pad oxide layer serves as a buffer layer, thus a stress between the silicon nitride layer and the semiconductor substrate can be released; then, after performing an annealing to the silicon nitride layer, etching the STI by using the silicon nitride layer as a mask to form a trench for filling isolation material constituting the STI in the semiconductor; then, performing an etch-back process to the silicon nitride layer and forming a lining oxide layer on a sidewall and a bottom of the trench; then depositing the isolation material to fill the trench; then grinding the isolation material layer to form the SIT; lastly, removing the remaining silicon nitride layer and pad oxide layer by etching, and performing a thermal oxide growth of the gate oxide layer and the depositing of the gate material layer, sequentially. According to the aforementioned manufacturing process, after the trench for filling the isolation material constituting the SIT in the substrate is formed, the top corner of the trench is exposed by performing the etch-back process to the silicon nitride layer. Thus when the lining oxide layer (constituting a side wall oxide layer of the STI) on the sidewall and the bottom of the trench is formed, the top corner of the trench can be smoother. When the gate oxide layer grows by a thermal oxidation process, the thickness of the gate oxide layer formed at the top corner of the STI is increased, however the increasing extent is very limited, thus the double humps effect cannot be remarkably improved. In addition, since the edge effect at a junction of the active region of the device and the top corner of the STI is inherent, the oxide layer (the lining oxide layer) formed in the trench of the STI can block an oxygen used in the thermal oxidation process from entering a silicon surface of the top corner of the STI, which causes the thickness of the gate oxide layer growing at this location to be thinner, thereby resulting in a low opening voltage of the device and the double humps effect of the VG-ID curve appears.

### SUMMARY OF THE INVENTION

Accordingly, it is necessary to provide a method of manufacturing a semiconductor device, which can eliminate a double humps effect of the device.

A method of manufacturing semiconductor device includes: providing a semiconductor substrate; forming a shallow trench isolation structure in the semiconductor substrate; forming a gate structure, the gate structure includes a gate oxidation layer and a gate material layer laminated on the gate oxidation layer; performing a first ion implantation to form a first doping ion in the gate material layer; performing a second ion implantation to form a second doping ion on a portion of the gate material layer located on a top corner of the shallow trench isolation structure, the second doping ion having a conductivity type opposite to the a conductivity type of the first doping ion.

By changing the distribution of the doped impurity in the gate material layer, the double humps effect of the device can be completely eliminated.

### BRIEF DESCRIPTION OF THE DRAWINGS

The following drawings form part of the specification and are included to further demonstrate certain embodiments or various aspects of the present disclosure. In the drawing:

FIGS. 1A to 1F are cross-section views of a device obtained corresponding to the steps according to a method of an embodiment;

FIG. 2 is a graphic diagram illustrating a VG-ID comparison of a device manufactured by a method of an embodiment and a device manufactured by a conventional process; and

FIG. 3 is a flowchart of a method of manufacturing a semiconductor device according to an embodiment.

### DETAILED DESCRIPTION OF THE EMBODIMENTS

In the following description, numerous specific details are set forth in order to provide a more thorough understanding of the present disclosure. However, it will be apparent to one skilled in the art that the present disclosure may be practiced without necessarily being limited to one or more of these specific details. In other instances, well-known technical features are not specific described, rather than in detail, in order to avoid obscuring the present disclosure.

In order to fully understand present disclosure, the specific steps will be provided in the following description for illustrating a semiconductor device and a method manufacturing the same and an electronic device provided by the present disclosure. Some embodiments of the resent disclosure are specifically described as follows. However, the invention may be embodied without necessarily being limited to these specific details.

It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Since the silicon dioxide constituting the gate oxide layer has a characteristic of boron attraction and phosphorus exclusion, a double humps effect usually occurs in a high-voltage (HV) device HVNMOS using a P-well, thus the present disclosure is specifically illustrated using HVNMOS as an example.

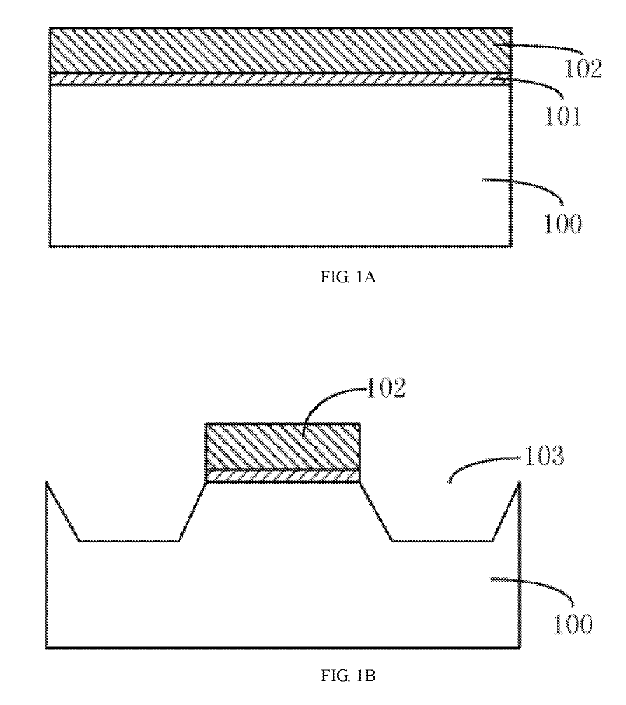

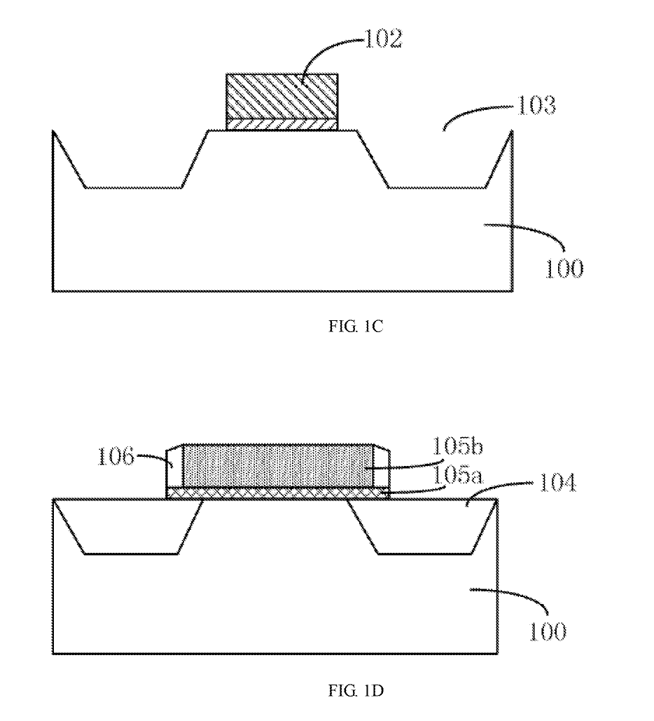

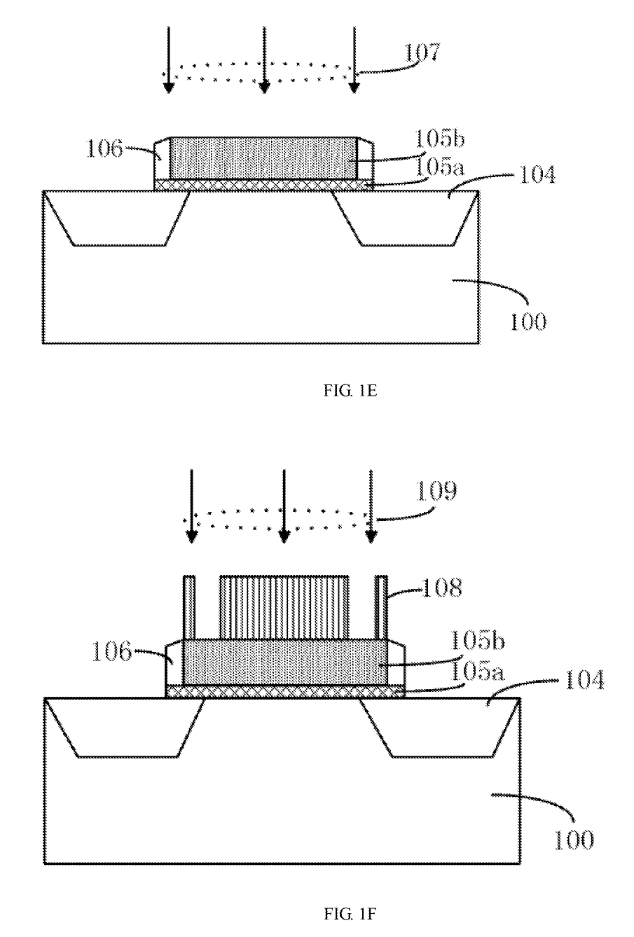

Referring to FIGS. 1A to 1F, FIGS. 1A to 1F are cross-sectional views of a device obtained corresponding to the steps according to a method of an embodiment.

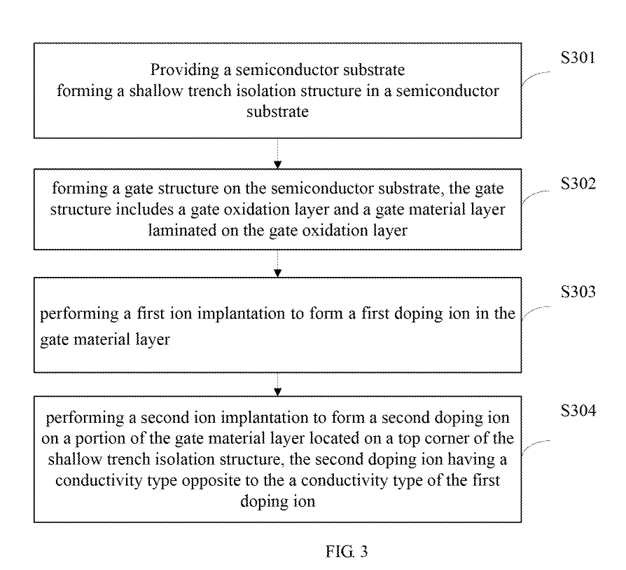

Referring also to FIG. 3, FIG. 3 is a flowchart of a method of manufacturing a semiconductor device according to an embodiment, which is used to briefly illustrate a total manufacturing process.

Firstly, in step S301, a semiconductor substrate is provided, and a shallow trench isolation structure is formed in the semiconductor substrate.

As shown in FIG. 1A, the semiconductor substrate 100 is provided, the constituent material of the semiconductor substrate 100 can adopt monocrystalline silicon, monocrystalline silicon doped with impurities, silicon on insulator (SOI), silicon stacking on insulator (SSOI), silicon germanide stacking on insulator (SiGeOI) and germanium on insulator (GeOI) and so on. As an example, in the illustrated embodiment, the constituent material of the semiconductor substrate 100 is made of monocrystalline silicon.

Then, a pad oxide layer 101 and a silicon nitride layer 102 is then deposited on the semiconductor substrate 100 sequentially. The pad oxide layer 101 serves as a buffer layer to release a stress between the silicon nitride layer 102 and the semiconductor substrate 100.

Next, as shown in FIG. 1B, after the silicon nitride layer 102 is annealed, an isolation region photolithography is performed by using the silicon nitride layer as a mask, and a trench 103 for filling isolation material is etched. As an example, the trench has a depth of 3000 angstroms to 8000 angstroms.

Next, as shown in FIG. 1C, an etch-back process is performed to the silicon nitride layer 102 to expose a top corner of the trench 103. As an example, a thickness of the removed silicon nitride layer 102 by the etch-back process along a direction parallel to a surface of the semiconductor substrate 100 can be 200 angstroms to 400 angstroms.

Next, as shown in FIG. 1D, the isolation material is deposited to fill the trench 103, so as to form the shallow trench isolation structure 104 in the semiconductor substrate 100. Prior to the depositing, the method further includes the step of forming a lining oxide layer on a sidewall and a bottom of the trench 103. After the depositing, the isolation material layer is grinded to flatten the top thereof. Then the remaining silicon nitride layer 102 and pad oxide layer 101 are removed by etching.

In step 302, a gate structure is formed on the semiconductor substrate, the gate structure includes a gate oxidation layer and a gate material layer laminated on the gate oxidation layer.

As shown in FIG. 1D, the gate structure includes the gate oxidation layer 105a and the gate material layer 105b laminated on the gate oxidation layer 105a. The gate oxidation layer 105a includes a silicon dioxide (SiO₂) layer, and the gate material layer 105b includes a polysilicon layer. The method of forming the gate oxidation layer 105a and the gate material layer 105b can adopt any conventional techniques familiar to those skilled in the art, such as chemical vapor deposition (CVD), low temperature chemical vapor deposition (LTCVD), low pressure chemical vapor deposition (LPCVD), rapid thermal chemical vapor deposition (RTCVD), plasma enhanced chemical vapor deposition (PECVD). Before the gate structure is formed, the method further includes the step of performing well region implantation, so as to form the well region in the semiconductor substrate 100. As for HVNMOS, the formed well region is P well.

Next, a sidewall structure 106 abutting the gate structure is formed on both sides of the gate structure. As an example, the sidewall structure 106 is made of oxide, nitride, or a combination thereof. The method of forming the sidewall structure 106 is familiar to those skilled in the art and will not be described in greater details.

Next, in step S303, a first ion implantation is performed, so as to form a first doping ion in the gate material layer.

As shown in FIG. 1E, the first ion implantation 107 is performed, so as to form the first doping ion in the gate material layer 105b. As for HVNMOS, the first doping ion is an N-type ion, which includes ions such as phosphorus, nitrogen, arsenic, antimony. bismuth

Next, in step S304, a second ion implantation is performed to form a second doping ion on a portion of the gate material layer located on a top corner of the shallow trench isolation structure. The second doping ion has a conductivity type opposite to the that of the first doping ion.

As shown in FIG. 1F, after a patterned mask layer 108 is formed on the gate material layer 105b, the second ion implantation 109 is performed to form the second doping ion on the portion of the gate material layer 105b located on the top corner of the shallow trench isolation structure 104. The second doping ion has the conductivity type opposite to the conductivity type of the first doping ion. As for HVNMOS, the second doping ion is a P-type ion, which includes ions such as aluminum, gallium, indium, thallium.

At this time, the process steps according to the method of the embodiments of the present disclosure are completed. After the mask layer 108 is removed, the fabrication of manufacturing the entire semiconductor device can be completed by a subsequent process, which includes: a source/drain region is formed on the semiconductor substrate 100; silicide is formed on the top of the source/drain region and the gate material layer 105b; a contact hole etch stop layer and an interlayer insulation film are sequentially formed on the semiconductor substrate 100, in which a contact hole connecting to the silicide at a bottom thereof is formed; a contact plug is formed in the contact hole; a first metal wiring layer connecting to the contact plug at a bottom thereof is formed; an intermetallic insulation layer covering the first metal wiring layer is formed, in which a second metal wiring layer connecting the first metal wiring layer is formed; another intermetallic insulation layer is formed, in which a third metal wiring layer connecting to the second metal wiring layer is formed. In this way, a multi-layer metal wiring structure is formed; a metal pad is formed for subsequent line bonding when the device is packaged.

A threshold voltage formula (1) of NMOS is as follows: The threshold voltage:

$${V}_{IN} = \frac{\vert {Q}_{SDma x}^{′} \vert}{{C}_{ox}} - \frac{{Q}_{ss}^{′}}{{C}_{ox}} + {φ}_{m s} + 2 {φ}_{fp} \qquad ( 1 )$$

In the formula, Φms represents a work function difference between the gate and the substrate. As for HVNMOS, the work function difference between the P-type substrate and the gate material layer doped with the N-type ion is less than a work function between the P-type substrate and the gate material layer doped with the P-type ion, and Φₘₛ usually has a negative value. Thus, by merits of reducing the doped concentration of the N-type ion or converting the N-type ion into a weak P-type ions by additional ion implantation, the threshold voltage of the HVNMOS can be increased.

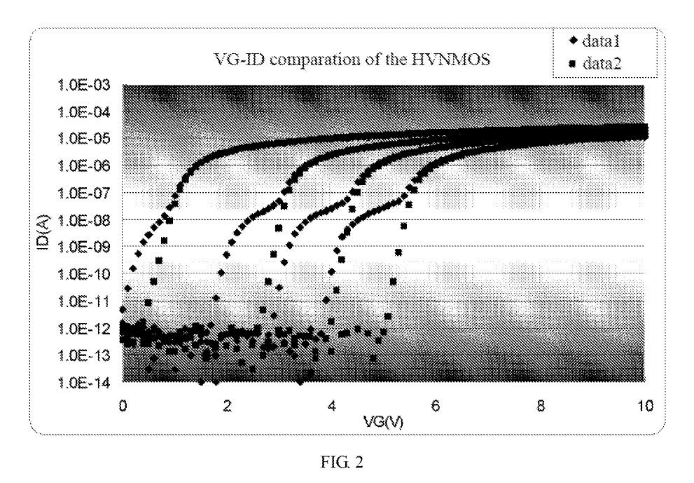

As shown in the curve composed of data 2 in FIG. 2, by changing the doped impurity concentration of the portion of the gate material layer 105b located on the top corner of the shallow trench isolation structure, an open voltage thereof can be increased. During the rise of a gate voltage of the device, the drain current can be delay to increase, therefore the leakage of the device can be improved and the double humps effect of the curve VG to ID can be eliminated.

The present disclosure also provides an electronic device, which includes the semiconductor device manufactured by the method of the exemplary embodiment of the present disclosure. The electronic device may be any electronic product or device such as a mobile phone, a tablet computer, a notebook computer, a netbook, a game machine, a television, a versatile compact disk (VCD), a digital video disk (DVD), a navigator, a camera, a video camera, a recording pen, a moving picture experts group audio layer-3 (MP3), a mobile Pentium 4 (MP4), and a playstation portable (PSP). In addition, the electronic device can be any intermediate product including the semiconductor device. The electronic device has a better performance due to the usage of the semiconductor device.

The aforementioned implementations are merely specific embodiments of the present disclosure, but are not intended to limit the protection scope of the present disclosure. It should be noted that persons skilled in the art can understand and embody all or part of flowcharts of the aforementioned implementations. Equivalent variation figured out by persons skilled in the art shall all fall within the protection scope of the present disclosure.

1. A method of manufacturing a semiconductor device, comprising:
forming a shallow trench isolation structure in a semiconductor substrate;
forming a gate structure on the semiconductor substrate, the gate structure comprising a gate oxidation layer and a gate material layer laminated on the gate oxidation layer;
performing a first ion implantation to form a first doping ion in the gate material layer; and
performing a second ion implantation to form a second doping ion on a portion of the gate material layer located on a top corner of the shallow trench isolation structure, the second doping ion having a conductivity type opposite to the a conductivity type of the first doping ion.

2. The method of claim 1, wherein the step of forming the shallow trench isolation structure comprises:
depositing a pad oxide layer and a silicon nitride layer on the semiconductor substrate sequentially;
performing a isolation region photolithography by using the silicon nitride layer as a mask, and etching a trench for filling isolation material;
performing an etch-back process to the silicon nitride layer to expose a top corner of the trench;
depositing the isolation material to fill the trench to form the shallow trench isolation structure in the semiconductor substrate; and
removing the remaining silicon nitride layer and the pad oxide layer by etching.

3. The method of claim 2, wherein the trench has a depth of 3000 angstroms to 8000 angstroms, a thickness of the silicon nitride layer removed by the etch-back process along a direction parallel to a surface of the semiconductor substrate is 200 angstroms to 400 angstroms.

4. The method of claim 2, wherein prior to the depositing, the method further comprises the step of forming a lining oxide layer on a sidewall and a bottom of the trench; after the depositing, the method further comprises the step of grinding the isolation material layer to flatten the top thereof.

5. The method of claim 1, wherein the first doping ion is a P-type ion, the second doping ion is an N-type ion.

6. A semiconductor device manufactured according to a method of claim 1.

7. An electronic device comprising a semiconductor device of claim 6.
